(19) United States
(12) Patent Application Publication
(10) Pub. No.: US 2022/0137723 A1
(43) Pub. Date: May 5, 2022

(54) FORCE SENSOR DEVICE AND METHOD FOR DETECTING FORCE BASED ON TEMPORAL OR SPATIAL DIFFERENTIAL IMAGE

(71) Applicant: PixArt Imaging Inc., Hsin-Chu City (TW)

(72) Inventors: Tien-Chung Yang, Hsin-Chu City (TW); Yi-Cheng Chiu, Hsin-Chu City (TW); Cheng-Chih Chang, Hsin-Chu City (TW); Jui-Te Chiu, Hsin-Chu City (TW); Yi-Chung Chen, Hsin-Chu City (TW)

(73) Assignee: PixArt Imaging Inc., Hsin-Chu City (TW)

(21) Appl. No.: 17/577,005

(22) Filed: Jan. 16, 2022

Related U.S. Application Data
(63) Continuation-in-part of application No. 17/191,572, filed on Mar. 3, 2021.
Application No. 17/191,572 is a continuation of application No. 16/395,226, filed on Apr. 25, 2019, now Pat. No. 10,969,878.
Application No. 16/395,226 is a continuation-in-part of application No. 15/681,415, filed on Aug. 20, 2017, now Pat. No. 10,372,155.

(51) Int. Cl. G06F 3/0338; G06F 3/03; G05G 9/047

(52) U.S. Cl. CPC G06F 3/0338; G05G 2009/04759; G05G 9/047; G06F 3/0308

(57) ABSTRACT

A force sensor device includes a first structure component, an optical sensor, and a flexible structure component. The optical sensor is disposed on the first structure component. The flexible structure component has a convex portion, and the flexible structure component is assembled with the first structure component to form a chamber in which the optical sensor is disposed. The optical sensor senses light ray transmitted from the flexible structure component to at least one pixel unit to generate at least one differential image and then detects a user's control force applied for the flexible structure component according to the at least one differential image. Differential image is temporal differential image, generated from successive pixel values of a single pixel unit, or is spatial differential image, generated based on temporal differential images of at least two neighboring pixel units.

### CROSS REFERENCE TO RELATED APPLICATIONS

This application is a continuation in part application of U.S. patent application Ser. No. 17/191,572, filed on 2021, Mar. 3, which is a continuation application of U.S. patent application Ser. No. 16/395,226, filed on 2019, Apr. 25, which is a continuation in part of U.S. application Ser. No. 15/681,415, filed on 2017, Aug. 20.

### BACKGROUND OF THE INVENTION

### 1. Field of the Invention

The invention relates to a force sensing scheme, and more particularly to a force sensor device and a method of the force sensor device.

### 2. Description of the Prior Art

Generally speaking, a conventional force sensor usually uses strain gauge/force-sensitive resistor or uses a Micro-Electro-Mechanical Systems (MEMS) sensor. However, such conventional force sensor has insufficiencies for industrial uses. For example, the conventional force sensor will be heavy weight or fragile, and it will need a complicated system design for implementations.

### SUMMARY OF THE INVENTION

Therefore one of the objectives of the invention is to provide a force sensor device and a corresponding method, to solve the above-mentioned problems.

According to embodiments of the invention, a force sensor device is disclosed. The force sensor device comprises a first structure component, an optical sensor, and a flexible structure component. The optical sensor has pixel units, and it is disposed on the first structure component. The flexible structure component has a convex portion, and the flexible structure component is assembled with the first structure component to form a chamber in which the optical sensor is disposed. The optical sensor is arranged for sensing light ray transmitted from the flexible structure component to at least one pixel unit to generate at least one differential image and then detecting a user's control force applied for the flexible structure component according to the at least one differential image; and, the at least one differential image is at least one temporal differential image, generated from successive pixel values of a single pixel unit, or is at least one spatial differential image, generated based on temporal differential images of at least two neighboring pixel units.

According to the embodiments, a method of a force sensor device is disclosed. The method comprises: providing a first structure component; providing an optical sensor having pixel units and disposed on the first structure component; using a flexible structure component having a convex portion, the flexible structure component assembled with the first structure component to form a chamber in which the optical sensor is disposed; sensing light ray transmitted from the flexible structure component to at least one pixel unit to generate at least one differential image; and detecting a user's control force applied for the flexible structure component according to the at least one differential image; the at least one differential image is at least one temporal differential image, generated from successive pixel values of a single pixel unit, or is at least one spatial differential image, generated based on temporal differential images of at least two neighboring pixel units.

According to the embodiments, the circuit cost can be significantly reduced, to achieve a lost-cost force sensor system. The response time can become fast and consumes less computing resource.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a section-view diagram of a force sensor device according to an embodiment of the invention.

FIG. 2 is a section-view diagram showing different scenario examples in which the force sensor device is placed in a still system and detects the user's control force according to an embodiment of the invention.

FIG. 3 is a section-view diagram of a force sensor device according to an embodiment of the invention.

FIG. 4 is a section-view diagram showing different scenario examples in which the force sensor device is placed in a moving system and detects the user's control force according to another embodiment of the invention.

### DETAILED DESCRIPTION

The invention aims at providing a technical solution of a force sensor device which is capable of using an optical sensing scheme to detect image patterns corresponding to the shape deformation caused by a user's different control behaviors such as different control forces, stresses, and/or directions, so as to accurately estimate and detect the user's different control behaviors. The circuit cost can be significantly reduced, to achieve a lost-cost force sensor system. The response time can become fast and consumes less computing resource.

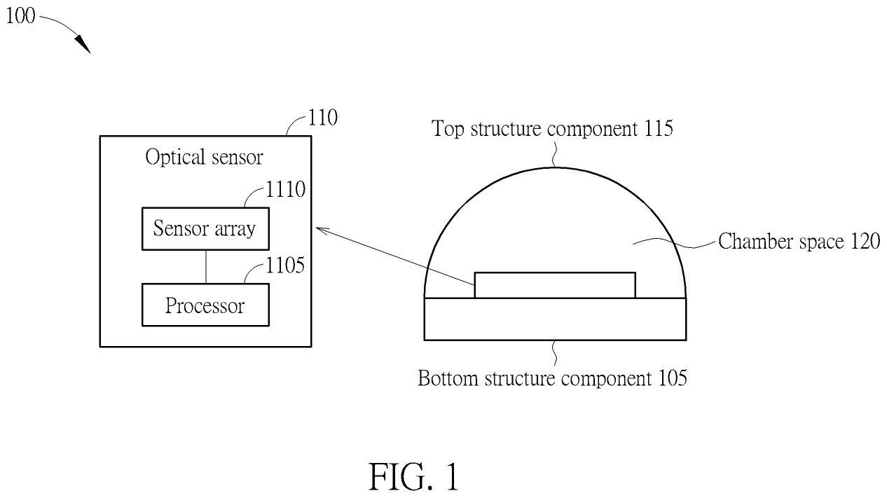

FIG. 1 is a section-view diagram of a force sensor device 100 according to an embodiment of the invention. The force sensor device 100 comprises a bottom structure component 105 such as a hard and inflexible component (but not limited), an optical sensor 110 having multiple pixel units, and a flexible/elastic top structure component 115 having a convex portion (but not limited), as shown in FIG. 1. The flexible top structure component 115 may have other portions with different shapes.

The optical sensor 110 is disposed on the top surface of the bottom structure component 105 which for example is a flexible printed circuit (FPC) or a printed circuit board (PCB); this is not intended to be a limitation. The flexible top structure component 115 is assembled with the bottom structure component 105 to form a chamber space 120 (such as an empty space or a space filled with other transparent or translucent material(s) to increase a user's feeling of control) in which the optical sensor 110 is disposed, as shown in FIG. 1. For instance, the flexible top structure component 115 can be a hemisphere made by a rubber film material; however, this is not meant to be a limitation. The flexible top structure component 115 can be made and implemented by using other materials and/or by other shapes/sizes. The shape of flexible top structure component 115 can be deformed by external forces and the distortion of the surface of flexible top structure component 115 can vary with the different forces such as shear or normal force.

The optical sensor 110 comprises a processor 1105 and a sensor array 1110 having multiple pixel units such as pixels or sub-pixels, and one or each pixel unit is used for sensing the light ray(s) transmitted from the flexible top structure component 115 so as to generate one or more pixel values.

In this embodiment, the force sensor device 100 may be disposed in a still system (but not limited) with no motions or almost no motions; that is, the force sensor device 100 is not moved or shifted. At least one portion of the flexible top structure component 115 may be implemented by using translucent or transparent material(s), and the light ray(s), transmitted from the flexible top structure component 115, may be associated with such translucent/transparent material(s). For example, the external ambient light ray(s) may penetrate through a translucent/transparent material, i.e. may be transmitted from an outer surface of the flexible top structure component 115 into an inner surface of the flexible top structure component 115 and then transmitted from such inner surface into the optical sensor 110. The optical sensor 110 can use the sensor array 1110 to sense the penetrated light ray(s) to generate one or more optical images.

In this embodiment, a pixel unit included in the sensor array 1110 for example is equivalent to an artificial intelligence (AI) pixel unit which can be arranged to sense the penetrated light ray to generate pixel values at different timings, i.e. successive pixel values, and to compare its generated successive pixel values to determine whether a pixel value changes so as to determine whether to generate and output a differential image, such as pixel-level difference information. The circuit cost can be significantly reduced, and this achieves a lost-cost force sensor system. Also, the AI pixel unit's response time is fast and only consumes less computing resource.

In the still system, for example, the condition of the external ambient light ray(s) changes unfrequently or almost rarely, and thus the condition of the penetrated light ray(s) also changes unfrequently or almost rarely. In this situation, when a difference between two successive pixel values (e.g. a current pixel value and a previous pixel value) generated by a pixel unit or a difference between the current pixel value and a reference pixel value of the pixel unit is smaller than a specific threshold, and the pixel unit in this condition is arranged to determine that the pixel value does not change and does not generate and output a differential image. A differential image can be a set of the difference(s) of pixel values. Alternatively, when the difference is larger than the specific threshold, the pixel unit in this condition is arranged to determine that the pixel value does change and the sensor array 1110 is arranged to generate and output a differential image to the processor 1105. Thus, the sensor array 1110 can output difference/differential image information in response to an event that the pixel unit detects the pixel value changes.

In practice, for example, a differential image, generated and outputted by the sensor array 1110, can be a temporal differential image which is a difference image obtained by difference pixel values of the same pixel captured in successive capturing times, and such temporal differential image with temporal intensity can be outputted from the sensor array 1110 to the processor 1105 of the optical sensor 110. Alternatively, in other embodiment, a differential image, generated and outputted by the sensor array 1110, can be a spatial differential image which may be a difference image obtained by difference pixel values captured between two neighboring or adjacent pixel units or may be a difference image obtained by difference pixel values of neighboring or adjacent pixel units' temporal differential pixel values. In the embodiments, a difference between the pixel unit's pixel value and a neighboring or adjacent pixel unit's pixel value can be used as a spatial differential image of the sensor array 1110. It should be noted that the sensor array 1110 in other embodiment may generate the temporal differential image and the spatial differential image respectively associated with the current optical image into the processor 1105. Thus, the optical sensor 110 can sense light ray(s) transmitted from the flexible top structure component 115 to the sensor array 1110 of the optical sensor 110 to generate at least one differential image such as temporal differential image(s) and/or spatial differential image(s). It should be noted that, the circuit design of the sensor array 1110 applied in the force sensor device 100 can make the force sensor device 100 have a fast response time since only partial pixel values are needed to be read out and transmitted to the processor 1105 and also save more power since the readout of an image with no pixel changes and the readout of a row with no pixel changes can be skipped.

In this embodiment, the flexible top structure component 115 has the translucent/transparent material portion. A user's different control behaviors/forces/directions, applied for the flexible top structure component 115, may block the external ambient light ray(s) with different angles/points/amounts and/or change the penetrated light ray(s) in different ways, and the optical sensor 110 can sense and detect the different changes of the penetrated light ray(s) to generate different image patterns corresponding to different differential image(s) so as to detect the user's different control behaviors/forces/directions. The processor 1105 of the optical sensor 110 can be arranged to detect a user's control force, which is applied for the flexible top structure component 115, based on the at least one differential image of the sensor array 1110.

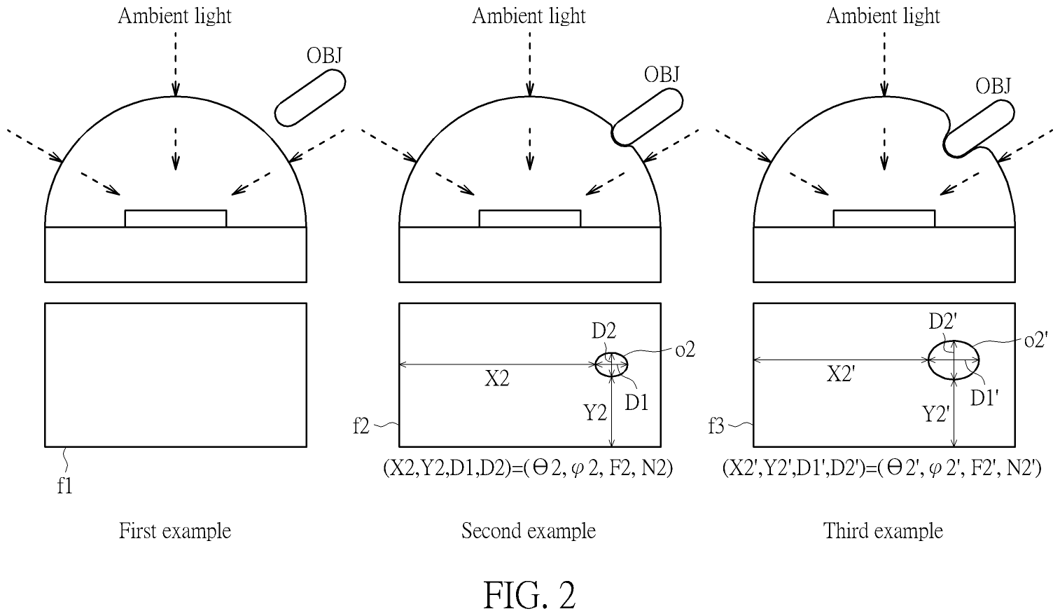

FIG. 2 is a section-view diagram showing different scenario examples in which the force sensor device 100 is placed in a still system (but not limited) and detects the user's control force according to an embodiment of the invention. As shown in FIG. 2, the object OBJ for example indicates a user's finger (but not limited), and the user's finger OBJ may touch identical/different positions at the outer surface of the flexible top structure component 115 with identical/different angles and/or may apply identical/different forces onto the outer surface of the flexible top structure component 115 so as to perform identical/different user control behaviors.

In the first example of FIG. 2, the user's finger OBJ does not touch and does not apply forces onto the flexible top structure component 115. In this situation, the shape of the flexible top structure component 115 does not change. One or more pixel units sense the penetrated light rays to generate pixel value(s) which is/are not larger than the specific threshold, and thus in this situation no differential images (or only very few differential images) are generated from the sensor array 1110 to the processor 1105. The processor 1105 for example generates a monitoring image/frame f1 which is identical a previous monitoring image such as a previous image sent from the sensor array 1110. A monitoring image generated by the processor 1105 can be regarded as a projection image of the light rays penetrated through the flexible top structure component 115. The processor 1105 based on the monitoring image f1 can determine that the force sensor device 100 is not touched or controlled by a user (i.e. the user does not perform a control operation), and the force sensor device 100 does not perform a corresponding operation in response to the event that no control behaviors occur.

In the second example of FIG. 2, the user's finger OBJ may lightly/softly touch the outer surface of the flexible top structure component 115 so as to perform a first user control behavior. In this situation, the shape of a portion of the flexible top structure component 115 lightly/softly changes. One or more pixel units sense the light rays to generate pixel value(s) which is/are larger than the specific threshold, and thus in this situation at least one differential image (temporal and/or spatial differential image(s)) corresponding to a small region of pixel units is generated by the sensor array 1110. For example, a smaller portion of pixel units may detect the pixel values changing due to the first user control behavior while other pixel units do not detect the pixel values changing, and then the sensor array 1110 outputs a corresponding differential image to the processor 1105. Thus, after receiving the corresponding differential image, the processor 1105 equivalently can generate a monitoring image f2, wherein the monitoring image f2 can be the corresponding differential image or can be formed by a combination of the corresponding differential image and a previous monitoring image. The monitoring image f2 comprises the image o2 which for example corresponds to the changed pixel values, and actually it for example (but not limited) may be a particular shadow image or image pattern which is formed due to that the ambient light ray at a particular portion/position/point is blocked by the user's first control behavior.

In practice, the displacement, size, and/or the shape of the differential image generated by the changed pixel values, e.g. the image o2, can be detected and calculated by the processor 1105 to estimate the user's control behavior. For instance, the image o2 for example may be a shadow image or image pattern having smooth circle edge(s) (but not limited), the image pattern may have a circle shape or any oval shapes. However, this is not intended to be a limitation. The image o2 may have a triangle shape, a trapezoid shape, or other shapes. The processor 1105 can detect and calculate the displacement, size, and/or the shape of the image o2 in the whole monitoring image f2. For example, the processor 1105 can calculate the X-axis pixel distance X2, Y-axis pixel distance Y2, the pixel distance D1, and the pixel distance D2 of the image o2, to precisely generate, calculate, and estimate the coordination point (θ2, φ2) at the outer surface of the flexible top structure component 115 touched by the user, the magnitude F2 of the force applied by the user, and the force direction N2 applied by the user. Thus, the optical sensor 110 (or force sensor device 100) can precisely detect and estimate the user's control operation and then perform a corresponding response operation in response to the user's control operation.

The displacement, size, and/or the shape of the differential image generated by the changed pixel values, e.g. the image o2, will be changed in response to a different user control behavior of the user. For example, in the third example of FIG. 2, the user's finger OBJ may heavily touch the outer surface of the flexible top structure component 115 so as to perform a second user control behavior different from the first user control behavior. In this situation, the shape of the portion of the flexible top structure component 115 heavily changes. Similarly, for example, a larger portion of pixel units may detect the pixel values changing due to the second user control behavior while other pixel units do not detect the pixel values changing, and then the sensor array 1110 outputs a corresponding differential image to the processor 1105. Thus, after receiving the corresponding differential image, the processor 1105 equivalently can generate a monitoring image f3, which can be the corresponding differential image or can be formed by a combination of the corresponding differential image and a previous monitoring image. The monitoring image f3 comprises the image o2′ which for example comprises the above-mentioned changed pixel values, and actually it for example (but not limited) another particular shadow image which is formed due to that the ambient light ray at a particular portion/position/point is blocked by the user's second control behavior.

Similarly, the displacement, size, and/or the shape of the image o2′ can be detected and calculated by the processor 1105 to estimate the user's second control behavior. For instance, the processor 1105 can calculate the X-axis pixel distance X2′, Y-axis pixel distance Y2′, the pixel distance D1′, and the pixel distance D2′ of the image o2′, to precisely generate, calculate, and estimate the coordination point (θ2′, φ2′) at the outer surface of the flexible top structure component 115 touched by the user, the magnitude F2′ of the force applied by the user, and the force direction N2′ applied by the user. Thus, the optical sensor 110 (or force sensor device 100) can precisely detect and estimate the user's control operation and then perform a corresponding response operation in response to the user's control operation.

In addition, for example, if the two monitoring images f2 and f3 are successive monitoring images generated by the processor 1105, then the processor 1105 can further estimate successive user control behaviors based on the image change between the images o2 and o2′ so as to determine that the user may perform a particular control operation or a particular sequence of control operations.

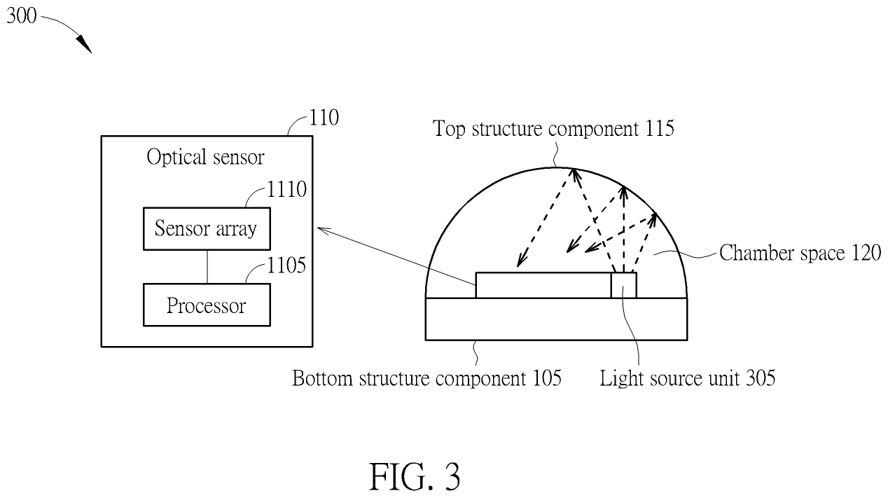

FIG. 3 is a section-view diagram of a force sensor device 300 according to another embodiment of the invention. The force sensor device 300 comprises the bottom structure component 105, the optical sensor 110 having multiple pixel units, a light source unit 305, and the flexible top structure component 115 having the convex portion. The light source unit 305 for example (but not limited) is a light emitting diode circuit which emits light rays to the inner surface of the flexible top structure component 115. The flexible top structure component 115 for example can be a hemisphere made by a material having opaque characteristics or a material with partially opaque characteristics (e.g. some portions/parts/spots of the material are implemented by using identical/different colors), so that the optical sensor 110 110 in this embodiment can be arranged to receive and sense the light rays, emitted from the light source unit disposed within the chamber space 120 and then at least partially reflected from the inner surface of the flexible top structure component 115, to generate the differential image(s) of a particular image pattern in response to a particular user control behavior. In other embodiments, the inner surface of the flexible top structure component 115 may be implemented by a highly reflective coating. The force sensor device 300 can be suitable for and applied in a moving system (but not limited) to accurately estimate the user's control behavior.

Further, it should be noted that the position/displacement of the light source unit 305 in the chamber space 120 can be disposed at any other positions, and this is not intended to be a limitation. In other embodiment, the light source unit 305 may be comprised within the optical sensor 110 110. In addition, the chamber space 120 in FIG. 3 can be an empty space or a space filled with other transparent or translucent material(s) to increase a user's feeling of control.

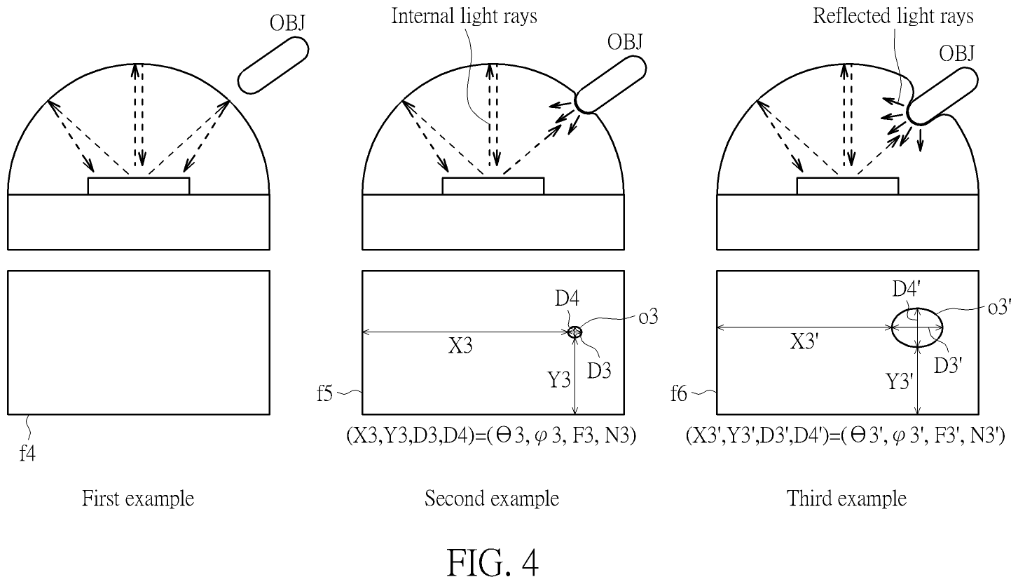

FIG. 4 is a section-view diagram showing different scenario examples in which the force sensor device 300 is placed in a moving system (but not limited) and detects the user's control force according to another embodiment of the invention. That is, the force sensor device 300 can be placed in a moving system or can be placed in a still system; for example, the force sensor device 300 can installed on a movable/rotatable machine or robot device. As shown in FIG. 4, for example, the light source unit 305 is implemented within and comprised by the optical sensor 300, and the optical sensor 300 can generate and emit the internal light rays to the inner surface of the flexible top structure component 115. The object OBJ for example indicates a user's finger (but not limited), and the user's finger OBJ may touch identical/different positions at the outer surface of the flexible top structure component 115 with identical/different angles and/or may apply identical/different forces onto the outer surface of the flexible top structure component 115 so as to perform identical/different user control behaviors.

In the first example of FIG. 4, the user's finger OBJ does not touch and does not apply forces onto the flexible top structure component 115. In this situation, similarly, the shape of the flexible top structure component 115 does not change. One or more pixel units sense the light rays, emitted from the light source unit 305 and reflected from the inner surface of the flexible top structure component 115, to generate pixel value(s) which is/are not larger than the specific threshold, and thus in this situation no differential images are generated from the sensor array 1110 to the processor 1105. The processor 1105 for example generates a monitoring image f4 which is identical a previous monitoring image such as a previous image. A monitoring image generated by the processor 1105 can be regarded as an image of the light rays reflected from the inner surface of the flexible top structure component 115. The processor 1105 based on the monitoring image f4 can determine that the force sensor device 300 is not touched or controlled by a user (i.e. the user does not perform a control operation), and the force sensor device 300 does not perform a corresponding operation in response to the event that no control behaviors occur.

In the second example of FIG. 4, the user's finger OBJ may lightly/softly touch the outer surface of the flexible top structure component 115 so as to perform a third user control behavior which can be different from or identical to the first user control behavior. In this situation, the shape of a portion of the inner surface of flexible top structure component 115 lightly/softly changes due to that control event of user's finger OBJ. One or more pixel units sense the light rays, emitted from the light source unit 305 and reflected from the inner surface of the flexible top structure component 115, to generate pixel value(s) which is/are larger than the specific threshold, and thus in this situation a differential image (temporal and/or spatial differential image(s)) corresponding to a small region of pixel units is generated from the sensor array 1110. After receiving the differential image, the processor 1105 equivalently can generate a monitoring image f5 which may be such differential image or a combination of the previous image and the differential image. The monitoring image f5 comprises the image o3 which for example comprises the changed pixel values, and actually it for example (but not limited) is a particular image pattern which is formed due to that the portion(s)/position(s)/point(s) emitted by the internal light rays are changed caused by the user's third control behavior. It should be noted that, in one embodiment, the displacement, size, and/or the shape of the image o2 in FIG. 2 corresponding to a user control behavior may be different from that of the image o3 in FIG. 4 corresponding to the same user control behavior. However, this is not meant to be a limitation. In other embodiment, the displacements, sizes, and/or the shapes of the images o2 and o3 may be identical.

Similarly, in practice, the processor 1105 can sense and calculate the displacement, size, and/or the shape of the image o3 to estimate the user's control behavior. For instance, the image o3 for example may be an image pattern having smooth circle edge(s) (but not limited), the image pattern may have a circle shape or any oval shapes. The image o3 may have a triangle shape, a trapezoid shape, or other shapes. The processor 1105 can detect and calculate the displacement, size, and/or the shape of the image o3 in the whole image f5 to calculate the X-axis pixel distance X3, Y-axis pixel distance Y3, the pixel distance D3, and the pixel distance D4 of the image o3, to precisely calculate and estimate the coordination point (θ3, φ3) at the outer surface of the flexible top structure component 115 touched by the user, the magnitude F3 of the force applied by the user, and the force direction N3 applied by the user.

The displacement, size, and/or the shape of the image o3 will be changed in response to a different user control behavior of the user. For example, in the third example of FIG. 4, the user's finger OBJ may heavily touch the outer surface of the flexible top structure component 115 so as to perform a fourth user control behavior different from the third user control behavior; the four user control behavior may be different from or identical to the second user control behavior. In this situation, the shape of the portion of the inner surface of the flexible top structure component 115 heavily changes, and the more portions/positions/points of the inner surface of the flexible top structure component 115, emitted by the internal light rays, are changed and shifted due to the larger shape change. A larger portion of pixel units can sense and detect more pixel values changing due to that the more portions/positions/points are shifted, and then the sensor array 1110 generates and outputs a corresponding differential image to the processor 1105. Thus, after receiving the differential image, the processor 1105 equivalently can generate a monitoring image f6 which may be the differential image or a combination of the differential image and a previous image such as the image f5 (but not limited). For example, the monitoring image f6 comprises the image o3′ which for example comprises the changed pixel values, and actually it for example (but not limited) is another particular image pattern which is formed due to that the inner light rays. The size of image pattern o3′ is larger than the size of image pattern o3.

For instance, the processor 1105 can calculate the X-axis pixel distance X3′, Y-axis pixel distance Y3′, the pixel distance D3′, and the pixel distance D4′ of the image o3′, to precisely generate, calculate, and estimate the coordination point (θ′, φ3′) at the outer surface of the flexible top structure component 115 touched by the user, the magnitude F3′ of the force applied by the user, and the force direction N3′ applied by the user. Thus, the optical sensor 110 (or force sensor device 300) can precisely detect and estimate the user's control operation and then perform a corresponding response operation in response to the user's control operation.

In addition, if the two monitoring images f5 and f6 are successive images generated by the processor 1105, then the processor 1105 can further estimate successive user control behaviors based on the image change between the image patterns o3 and o3′ so as to determine that the user may perform a particular control operation or a particular sequence of control operations.

Further, in other embodiments of FIG. 3/FIG. 4, an identification element (e.g. particular pattern(s) with different color(s)) can be formed on the inner surface of the flexible top structure component 115, to improve the detection sensitivity of a pixel unit for detecting whether a pixel value changes.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A force sensor device, comprising:
a first structure component;
an optical sensor having pixel units, disposed on the first structure component; and
a flexible structure component having a convex portion, the flexible structure component assembled with the first structure component to form a chamber in which the optical sensor is disposed;
wherein the optical sensor is arranged for sensing light ray transmitted from the flexible structure component to at least one pixel unit to generate at least one differential image and then detecting a user's control force applied for the flexible structure component according to the at least one differential image; and, the at least one differential image is at least one temporal differential image, generated from successive pixel values of a single pixel unit, or is at least one spatial differential image, generated based on temporal differential images of at least two neighboring pixel units.

2. The force sensor device of claim 1, wherein the optical sensor is arranged to determine a coordination position, a magnitude, or a direction of the user's control force applied for the flexible structure component by detecting a displacement, a size, or a shape of the at least one differential image.

3. The force sensor device of claim 1, wherein the at least one pixel unit is used for determining whether to generate the at least one temporal differential image by sensing a pixel difference between the successive pixel values.

4. The force sensor device of claim 1, wherein the flexible structure component has a translucent material through which the sensed light ray is an ambient light ray transmitted from an outer surface of the flexible structure component to an inner surface of the flexible structure component, and the force sensor device is to be disposed on a still system.

5. The force sensor device of claim 1, further comprising:
a light emitting circuit, disposed in the chamber, for emitting the light ray to an inner surface of the flexible structure component;
wherein the optical sensor is arranged for sensing the light ray reflected from the inner surface of the flexible structure component to generate the at least one differential image; and,
the force sensor device is to be disposed on either a still system or a moving system.

6. The force sensor device of claim 5, wherein the flexible structure component has an opaque material which is used for reflecting the light ray to the optical sensor.

7. The force sensor device of claim 6, wherein an identification element is formed on the inner surface of the flexible structure component.

8. The force sensor device of claim 1, wherein the flexible structure component is a hemisphere made by a rubber film material.

9. A method of a force sensor device, comprising:
providing a first structure component;
providing an optical sensor having pixel units and disposed on the first structure component;
using a flexible structure component having a convex portion, the flexible structure component assembled with the first structure component to form a chamber in which the optical sensor is disposed;
sensing light ray transmitted from the flexible structure component to at least one pixel unit to generate at least one differential image; and
detecting a user's control force applied for the flexible structure component according to the at least one differential image;
wherein the at least one differential image is at least one temporal differential image, generated from successive pixel values of a single pixel unit, or is at least one spatial differential image, generated based on temporal differential images of at least two neighboring pixel units.

10. The method of claim 9, wherein the detecting step comprises:
using the optical sensor to detect a displacement, a size, or a shape of the at least one differential image to determine a coordination position, a magnitude, or a direction of the user's control force applied for the flexible structure component.

11. The method of claim 9, wherein the optical sensor comprises at least one pixel unit used for determining whether to generate the at least one temporal differential image by sensing a pixel difference between the successive pixel values.

12. The method of claim 9, wherein the flexible structure component has a translucent material through which the sensed light ray is an ambient light ray transmitted from an outer surface of the flexible structure component to an inner surface of the flexible structure component, and the force sensor device is to be disposed on a still system.

13. The method of claim 9, further comprising:
using a light emitting circuit disposed in the chamber to emit the light ray to an inner surface of the flexible structure component; and
using the optical sensor to sense the light ray reflected from the inner surface of the flexible structure component to generate the at least one differential image;
wherein the force sensor device is to be disposed on either a still system or a moving system.

14. The method of claim 13, wherein the flexible structure component has an opaque material which is used for reflecting the light ray to the optical sensor.

15. The method of claim 14, further comprising:
providing an identification element to be formed on the inner surface of the flexible structure component.

16. The method of claim 9, wherein the flexible structure component is a hemisphere made by a rubber film material.
